(19) United States
(12) Patent Application Publication
(10) Pub. No.: US 2024/0047992 A1
(43) Pub. Date: Feb. 8, 2024

(54) METHODS AND SYSTEMS FOR REMOTELY CONTROLLING SMART ELECTRICAL SWITCHES AND ASSOCIATED DEVICES USING ANALYTICS

(71) Applicant: UBIQ AUTOMATIONS PRIVATE LIMITED, Bangalore (IN)

(72) Inventors: Kishan M. BHAY, Bangalore (IN); Apurva Dhar DUBEY, Chhattisgarh (IN)

(21) Appl. No.: 18/258,773

(22) PCT Filed: Dec. 21, 2021
(86) PCT No.: PCT/IN2021/051192

§ 371 Date: Jun. 21, 2023

(30) Foreign Application Priority Data
Dec. 21, 2020 (IN) 202041055592

(51) Int. Cl. H02J 13/00; G01R 19/25; H04L 12/28

(52) U.S. Cl. CPC H02J 13/00036; H02J 13/00001; G01R 19/2513; H04L 12/2816; H02J 13/00006; G05B 19/042

(57) ABSTRACT

Embodiments disclosed herein relate to electrical switches, and more particularly to remotely controlling electrical switches and associated devices. A method disclosed herein includes collecting condition monitoring data of devices by smart electrical switches. The method further includes analyzing the condition monitoring data of the devices for predictive maintenance and controlling of the smart electrical switches and the associated devices.

### RELATED APPLICATIONS

The present application is a National Phase of International Application Number PCT/IN2021/051192, filed Dec. 21, 2021, and claims the priority of India Application No. 202041055592, filed Dec. 21, 2020,

### TECHNICAL FIELD

Embodiments disclosed herein relate to electrical switches, and more particularly to remotely controlling electrical switches and associated devices.

### BACKGROUND

Smart electrical switches are electrical switches that include communication capabilities. The smart electrical switches may be a part of a home wireless network (Wi-Fi) through Wi-Fi interface (2.4 or 5 GHz), wireless personal area network (WPAN) through a networking protocol such as BLE, Zigbee, or Thread (2.4 GHz), and so on in either a star topology or a mesh topology. The switches may also be connected to the Internet.

In an example conventional approach, a user may be enabled to control the smart electrical switches using at least one of, but is not limited to, a mobile phone (via an application), a smart virtual assistant, and so on. However, controlling the smart electrical switches using the mobile phone and the smart virtual assistant may involve transmission of control commands to the smart electrical switches through multiple networking layers, which may be slower and not efficient. Further, controlling the smart electrical switches using the smart virtual assistants requires installation of separate virtual assistant devices in a surrounding environment of the smart electrical switches.

In another example conventional approach, the smart electrical switches may be provided with hardware controllers/switch modules, that enable the user to control the smart electrical switches and to track status of the smart electrical switches and associated devices. However, the hardware controllers may be non-intuitive and impact installation process.

In yet another example conventional approach, the smart electrical switches may be provided with “bells and whistles” (a metaphor to explain that traditional smart electrical switches come with extra components or features that may be unnecessary) for providing the status of the smart electrical switches to the user. However, integration of the “bells and the whistles” with the smart electrical switches may be expensive.

Thus, the above conventional approaches do not involve an efficient mechanism for remotely controlling the switches and the associated devices by applying the control commands directly on the switch modules associated with the smart electrical switches, as the switch modules may be implemented behind the walls.

Further, in the conventional approaches, the status of the smart electrical switches and the associated devices may be shared with the user or electrical utility service providers. However, the status may only provide information about an ON or OFF state of the smart electrical switches and the associated devices. Thus, the electrical utility service providers may need to resort to load shedding mechanisms in order to avoid excessive load on the grid, as the status of the smart electrical switches and the associated devices may not provide information such as, but are not limited to, power consumption by each device, power fluctuations on each device, power load on each device, or the like.

In addition, the conventional approaches do not involve any mechanisms to identify and communicate anomalies associated with the smart electrical switches and the associated devices to the user. Thus, the user has to go through the hassles of tedious tasks to identify and resolve the anomalies associated with the smart electrical switches and the associated devices, when the smart electrical switches and/or the associated devices do not operate.

### Objects

The principal object of embodiments herein is to disclose methods and system for remotely controlling electrical switches and associated devices.

These and other aspects of the embodiments herein will be better appreciated and understood when considered in conjunction with the following description and the accompanying drawings. It should be understood, however, that the following descriptions, while indicating at least one embodiment and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF FIGURES

Embodiments herein are illustrated in the accompanying drawings, through out which like reference letters indicate corresponding parts in the various figures. The embodiments herein will be better understood from the following description with reference to the drawings, in which:

FIG. 1 depicts a control system for remotely controlling smart electrical switches and associated devices, according to embodiments as disclosed herein;

FIG. 2 depicts another embodiment of a control system for remotely controlling two kinds of electrical switches and associated devices, according to embodiments as disclosed herein;

FIGS. 3a and 3b depict the smart electrical switch, according to embodiments as disclosed herein;

FIG. 4 is an example block diagram depicting components of a switch controller, according to embodiments as disclosed herein;

FIG. 5 is a flow diagram depicting functionalities of the smart electrical switch(es), according to embodiments as disclosed herein; and

FIG. 6 is a flow diagram depicting a method for maintenance and controlling of the smart electrical switches and the associated devices, according to embodiments as disclosed herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

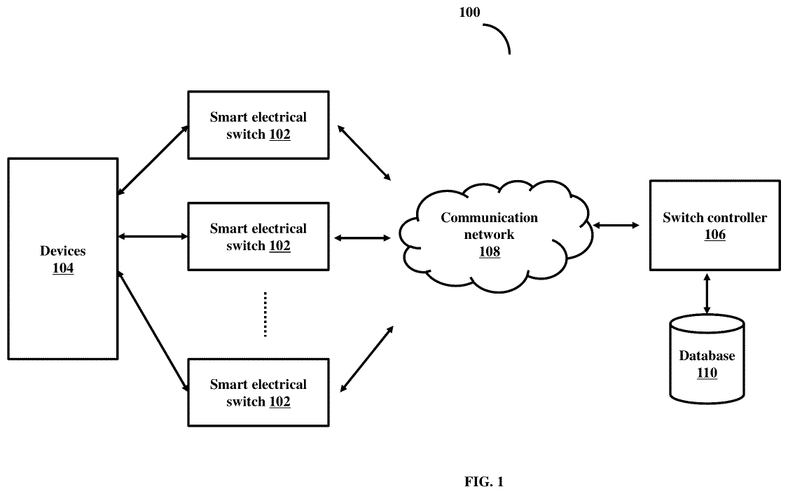

Embodiments herein disclose methods and systems for remotely controlling smart electrical switches and associated devices. Referring now to the drawings, and more particularly to FIGS. 1 through 6, where similar reference characters denote corresponding features consistently throughout the figures, there are shown embodiments.

FIG. 1 depicts a control system 100 for remotely controlling smart electrical switches (also referred to herein as a master switch) and associated devices, according to embodiments as disclosed herein.

The control system 100 includes smart electrical switches 102, devices 104 coupled with the smart electrical switches 102, and a switch controller 106. In an example, the smart electrical switches 102 and/or the devices 104 may connect with the switch controller 106 through a communication network 108. The communication network 108 include at least one of, but is not limited to, a wired network, a value added network, a wireless network, a satellite network or a combination thereof. Examples of the wired network may be, but are not limited to, a Local Area Network (LAN), a Wide Area Network (WAN), an Ethernet, and so on. Examples of the wireless network may be, but are not limited to, a cellular network, a wireless LAN (Wi-Fi), Bluetooth, Bluetooth low energy, Zigbee, Wi-Fi Direct (WFD), Ultra-wideband (UWB), infrared data association (IrDA), near field communication (NFC). The system 100 may further include a security element that can encrypt and decrypt all communication occurring between and with the components of the system 100 over the communication network 108, such as, but not limited to, communication between the smart switch 102 and the device 104, communication between the smart switch 102 and the switch controller 106, communication between the power base 202 and user controller 204, and communication with the user controller 204 through a mobile application. In another example, the smart electrical switches 102 and/or the devices 104 may connect with the switch controller 106 directly (for example: via a direct communication, via an access point, and so on). In another example, the smart electrical switches 102 and/or the devices 104 may connect with the switch controller 106 via a relay, a hub, and a gateway. It is understood that the smart electrical switches 102 and/or the devices 104 may be connected with the switch controller 106 in any of various manners (including those described above) and may be connected to each other in two or more of various manners (including those described above) at the same time.

The smart electrical switches 102 and the devices 104 may be deployed in a target eco-system. In an example, the target eco-system may be an Internet of Things (IoT) environment (for example: a smart home environment, a smart office environment, or the like). In another example, the target eco-system may be an individual room within a household or an entire household or a group of households within a housing community. In another example, the target eco-system may be a building that houses commercial establishments (for example; malls, hotels, hospitals, government offices, enterprises, and so on). In another example, the target eco-system may be grouped together to create a larger eco-system.

The smart electrical switches 102 are electrical switches that include communication capabilities and controls operations of the devices 104. The devices 104 may be at least one of, but is not limited to, home appliances, lighting devices, or any other devices that may be connected with the smart electrical switches 102 and operated/controlled via the smart electrical switches 102. Examples of the devices 104 may be, but are not limited to, a light, a computer, a television, a digital video disk (DVD) player, an audio device, a refrigerator, an air conditioner, an air purifier, a vacuum cleaner, an oven, microwave, a washing machine, a dryer, a set-top box, a home automation control panel, a security control panel, a game console, and so on. The smart electrical switches 102 may use a radio transmitter supporting the communication network 108 to communicate with each other and the devices 104.

In an embodiment, the smart electrical switches 102 may be mounted on walls. In another embodiment, the smart electrical switches 102 may be implemented inside the respective devices 104.

The smart electrical switches 102 may be controlled remotely by at least one of, a user, an external service provider, or the like for controlling the operations of the devices 104. In an example, the external service providers may be, but are not limited to, device Original Equipment Manufacturers (OEMs), maintenance service providers, property management service providers, utilities, healthcare personnel, and so on. In an example, the smart electrical switches 102 may be controlled using a user interface provided on the smart electrical switches 102. The user interface may include at least one of, but is not limited to, a display with a touch screen, one or more push buttons, one or more slider switches, and so on. The user may change a status (i.e., turning ON or turning OFF) or configurations of the smart electrical switches using the user interface when the status and the configurations are provided on the user interface (i.e., the display with the touch screen). In another example, the smart electrical switches 102 may be controlled using an application configured on the user computing device that is being used by the user or the external service provider. Examples of the user computing device may be, but is not limited to, a smart phone, a mobile phone, a video phone, a computer, a tablet personal computer (PC), a netbook computer, a laptop, a wearable device, a personal digital assistant (PDA), a workstation, a server, and so on. In another example, the smart electrical switches 102 may be controlled using voice commands, when the smart electrical switches 102 include a voice user interface.

In an embodiment, the user may define at least one of, dependency and inter-dependency switch(es), compatible devices, and so on, using the application configured on the user device. The smart electrical switch may control the devices 104 based on the dependency defined. If any of the dependent switch(es) and/or device(s) are not available for control, the user is notified for troubleshooting and/or to perform corrective action(s).

In an embodiment, the user may discover various smart electrical switches 102 and the devices 104 available for control using the mobile application configured on the user computing device. On discovering the smart electrical switches and the devices 104, the user may assign identifiers to the smart electrical switches 102 and/or the devices 104. The identifiers may include at least one of, a switch identifier (switch ID), location identifiers (location IDs), and a user identifier (user ID or customer ID). The switch ID may be used to uniquely identify the smart electrical switch 102. The location identifiers of the smart electrical switch may indicate provide location information of the switch. In an example, the location IDs may include at least one of, a room ID, a home ID, or the like. The user ID may be used to provide information about the user, who controls the switch. In an embodiment, the smart electrical switches may be grouped for smart scene controls, wherein each group of switches may correspond to a scene and may be assigned with a group ID and each switch may be assigned with a unique address. In such a scenario, a status of each switch may be defined within the group and each switch may receive a message or new status from the switch of the other or same group as a part of a scene. Similarly, each of the devices 104 associated with the smart electrical switches 102 may be assigned with a device ID. The user may communicate the identifiers assigned to the smart electrical switches 102 and/or the devices 104 to the switch controller 106 for storage. It is to be understood that the terms “smart electrical switch,” “smart switch,” or “master switch” may be used interchangeably to refer to the component referenced by the numeral 102 that is capable of connecting with device 104 and/or operating/controlling device 104.

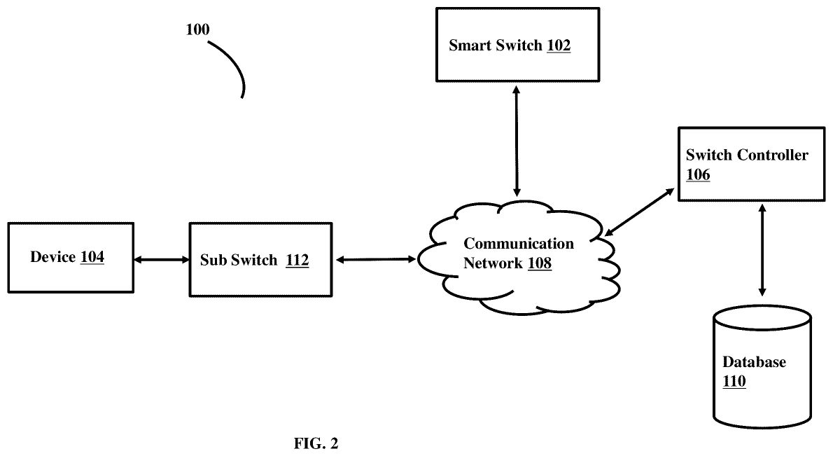

FIG. 2 illustrates another embodiment of the control system 100, according to embodiments disclosed herein. The smart switch 102 may operate/control the device 104 via a sub switch 112. The sub switch 112 may be connected to the device 104, and the sub switch 112 may communicate with the smart electrical switch 102 through a communication network 108. The communication network 108 between the sub switch 112 and smart switch 102, may be different from the communication network 108 between the smart switch 102 and switch controller 106. The sub switch 112 may simultaneously communicate with the smart electrical switch 102 and the switch controller 106. The advantage with this embodiment is that if the sub switch 112 may be unable to directly transmit data to the switch controller 106, the sub switch 112 may still be able to transmit data to the switch controller 106 through the smart electrical switch 102. The system 100 may further include a security element that encrypts and decrypts all communication between and with components of the system 100 over communication network 108, such as, but not limited to, communication between the sub switch 112 and the device 104, communication between the sub switch 112 and the smart switch 102, communication between the sub switch 112 and the switch controller 106, communication between the smart switch 102 and the switch controller 106, and communication with the sub switch 112 and the smart switch 102 through a mobile application.

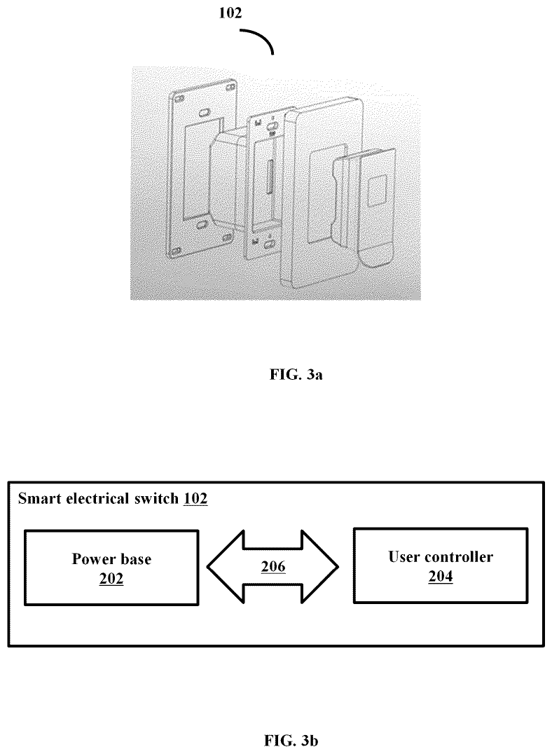

The smart electrical switch 102 is depicted in FIGS. 3a and 3b. As depicted in FIG. 3b, the smart electrical switch 102 includes a power base 202, and a user controller 204.

In an embodiment, the power base 202 and the user controller 204 may be implemented on a single electronic board. In an embodiment, the power base 202 and the user controller 204 may be connected using one or more plug type connectors 206. The plug type connectors 206 may be configured to provide DC power supply required for operating the user controller 204, when the user controller 204 is plugged into the power base 202 using the plug type connectors 206 with receptacle at one end and header at the other end. The plug type connectors 206 may also provide mechanical stability to the plug type connectors 206 apart from the power supply. The plug type connectors 206 may be polarized, so that the user may not plug the power base 202 and the user controller 204 in a wrong direction. When the user controller 204 is not plugged into the power base 202, a battery of the user controller 204 may provide the power supply to the user controller 204 for operating.

In another embodiment, the power base 202 and the user controller 204 may be connected using one of pogo-pin, or sping-loaded pin, or compression type, or slide type or any other insertion-less connectors. The magnets in these connectors may be used to provide mechanical stability.

In an embodiment, the smart electrical switch 102 does not include the one or more plug type connectors 206. In such a case, the user controller 204 may be operated using the power supplies that may be provided by a rechargeable battery. The rechargeable battery may be inductively charged via wireless charging coils. The wireless charging coils may include a receiving coil that may be present in the user controller 204 and a transmitting coil that may be present in the power base 202.

The power base 202 may be configured to provide electrical power for powering the devices 104 associated with the smart electrical switches 102. The power base 202 can include components such as, but are not limited to, an Alternate Current (AC)-Direct Current (DC) converter, one or more DC voltage regulators, a coin cell battery, a relay, one or more sensors for measuring at least one of, AC line voltage, current, and power factor, a microcontroller, a radio frequency transceiver, or any other circuitry required for functioning the components of the power base 202. In an example, the relay may include at least one of, an electromechanical relay, a solid state relay, a reed relay, a triac relay, and so on. The power base 202 may be configured to also stop the supply of power to devices 104 associated with the smart switches 102 with the help of the relay. The AC-DC converter or coin cell battery can help provide DC power supply to the DC circuitry of the power base 202, with the voltage regulator stabilizing the DC power supply. The power base 202 may include a power measurement element, such as an integrated circuit or a circuit comprising of discrete components such as, but not limited to, comparators, resistors, capacitors, and inductors, for measuring the power consumption of a device 104, voltage, current, and power factor. The microcontroller can receive this power measurement data and transmit this data to the user controller 204 and/or the switch controller 106. The microcontroller within the power base 202 may also receive switching commands from the user controller 204 and/or switch controller 106 and transmit it to the relay. The radio frequency transceiver can help in enabling communication between the power base 202 and the user controller 204 and the switching controller 106.

The user controller 204 may be disconnected from the power base 202, such that the user controller 204 may continue to function despite not being physically connected to the power base 202 through a battery in the user controller 204 that provides it with power supply. The user controller 204 also may be remotely operated to control the respective smart electrical switch 102 or other smart electrical switches 102 that may be part of the same target eco-system. Also, the user controller 204 may also be used as a charging device, which may provide charging facility to the user devices via a Universal Serial Bus (USB) charging port provided on the user controller 204.

The user controller 204 can include components such as, but are not limited to, the user interface, one or more DC-DC voltage regulators, a battery, battery charging modules, battery management modules and circuits, power management modules and circuits, a microcontroller, a radio frequency transceiver, a digital audio processor, a communication interface, a memory, one or more sensors, a microphone, a speaker, or any other circuitry required for functioning of the components of the user controller 204. In an example, the battery of the user controller 204 may include at least one of, but is not limited to, a coin cell battery, a rechargeable coin cell battery, a rechargeable lithium polymer battery (Li—Po) battery, or any other rechargeable battery. In an example, the one or more processors of the user controller 204 may include at least one of, a digital signal processor (DSP), an image signal processor (ISP), and so on. In an example, the one or more sensors of the user controller 204 may be used to measure at least one of, proximity of user with respect to the smart electrical switches 102 and/or the devices 104, ambient light conditions, infrared motion detection, temperature, air quality, gas detection, smoke, and so on. Examples of the one or more sensors may be, but are not limited to, a temperature sensor, a humidity sensor, an infrared sensor, a gyroscope sensor, an atmospheric sensor, a proximity sensor, an RGB sensor (a luminance sensor), a photosensor, a thermostat, an Ultraviolet (UV) light sensor, a fire detection sensor, a smoke sensor, or any other equivalent sensor. A function of each sensor may be intuitively inferred by one of ordinary skill in the art based on its name, and thus, its detailed description is omitted. The microcontroller may be configured to process actions/inputs/commands received from the user and/or the external service provider and/or the switch controller 106 into switching commands and provide the switching commands to control the devices 104 for controlling their operations. The communication interface may enable the user controller 204 of the smart electrical switch 102 to communicate with other devices such as, but are not limited to, other smart electrical switches, the switch controller 106, the devices 104, the user devices, and so on using communication methods/protocols supported by the communication network 108. The communication methods/protocols supported by the communication network 108 may include encryption and decryption protocols.

The user controller 204 may also include an independent Radio Frequency (RF) transceiver, that enables the user controller to act as a separate node in the target eco-system. Each node can have a unique address, which can enable the user controller 204 to transmit messages to an intended recipient (for example: the user and/or the external service provider (the user device), the switch controller 106, or the like) and also receive messages from the intended recipient.

In an embodiment, the smart electrical switch 102 may also include a voltage protection circuitry (not shown) along with the power base 202 and the user controller 204. The voltage protection circuitry provides protection to the connected devices 104 against overvoltage, under-voltage, which enhances the lifecycle of the connected devices 104.

The smart electrical switch 102 may be configured to collect condition monitoring data of the connected devices 104 and communicate the collected condition monitoring data of the connected devices 104 to the switch controller 106.

The smart electrical switch 102 can collect the condition monitoring data of the connected devices 104 using the one or more sensors included in the power base 202 and the user controller 204. The condition monitoring data may indicate conditions/parameters of the devices 104 connected with the smart electrical switch 102 and the associated target eco-system. In an example, the condition monitoring data may include information such as, but not limited to, current, voltage, power, and power factor of the devices 104, time of the day (i.e., timestamp), a number of users present within the surrounding environment of the devices 104, a type of location/room, where the devices 104 have been present, status of occupancy of the users within the surrounding environment of the devices 104, a target device, a profile of the target device, target and control parameters of the devices 104, ambient light conditions, temperature, air quality, gas detection, and so on.

In an example, the smart electrical switch 102 may collect the condition monitoring data of the connected devices 104 continuously/in real-time. In another example, the smart electrical switch 102 may collect the condition monitoring data of the connected devices 104 at periodic intervals of time. In another example, the smart electrical switch 102 may collect the condition monitoring data of the connected devices 104 on detecting occurrence of events. Examples of the events may be, but are not limited to, the conditions/parameters of the devices 104 and/or the associated target eco-system exceeding a pre-defined threshold, turning ON or OFF of the devices 104, or the like.

On collecting the condition monitoring data of the connected devices 104, the smart electrical switch 102 can process the collected condition monitoring data using the one or more processors included in the user controller 204. The smart electrical switch 102 can communicate the processed condition monitoring data of the connected devices 104 to the switch controller 106 using the communication interface included in the user controller 204. In an embodiment, the smart electrical switch 102 may communicate the condition monitoring data of the devices 104 with other relevant details to the switch controller 106. The other details may include at least one of, but is not limited to, a switch ID, a device ID, a home ID, a room ID, a user ID, and so on. Also, the smart electrical switch 102 may communicate the condition monitoring data of the devices 104 to the user and/or the external service provider.

The switch controller 106 referred herein may be a cloud computing device (can be a part of a public cloud or a private cloud), a server, a computing device, and so on. The server may be at least one of a standalone server, a server on a cloud, or the like. The computing device may be, but is not limited to, a personal computer, a notebook, a tablet, desktop computer, a laptop, a handheld device, a mobile device, and so on. Also, the switch controller 106 may be at least one of, a microcontroller, a processor, a System on Chip (SoC), an integrated chip (IC), a microprocessor based programmable consumer electronic device, and so on.

The switch controller 106 may be coupled with a database 110. The database 110 may store at least one of, the switch ID, the device ID, the room ID, the home ID, the user ID, or the like associated with each smart electrical switch 102 and the associated devices 104, load regulation criteria (which has been set by the user and/or the external service provider), the unique address of each smart electrical switch 102, previous usage patterns of the smart electrical switches 102 and the associated devices 104, and so on.

In an embodiment, the switch controller 106 may be configured to determine usage context of the devices 104 in the target eco-system by analyzing the condition monitoring data of the devices 104 received from each smart electrical switch 102. The usage context of the devices 104 may indicate at least one of, periods of inactivity of the devices 104, absence of users from the surrounding environment of the devices 104 while the devices 104 are being operating, operation of the devices 104 irrespective of user behavior and/or the parameters of the respective target eco-system, and so on. Based on the determined usage context of the devices 104, the switch controller 106 may generate control notification(s)/commands to perform necessary actions on the devices 104. The necessary actions may include controlling the operations of the devices 104 with respect to the conditions/parameters of the target eco-system. The switch controller 106 can send the control notification to the smart electrical switches 102 associated with the respective devices 104 to perform the necessary actions on the devices 104. Also, the switch controller 106 can send the control notification to the user and/or the external service provider to perform the necessary actions on the devices 104. In an example, the necessary action may be controlling the devices 104 to suit the user behavior based on weather conditions (such as, sunrise and sunset, ambient light conditions, humidity, temperature, and so on), and floor plan of a household, or the like. In another example, the necessary action may include turning OFF the devices 104 to conserve energy, on detecting the period of inactivity of the devices 104, based on quiescent power consumption, absence of user(s) from the target ecosystem, and so on.

In an example, the smart electrical switches 102 may perform the necessary actions on the devices 104 on their own. In another example, the smart electrical switches 102 may perform the necessary actions on the devices 104 by considering necessary conditions/parameters being satisfied by the status of the sensors in other smart electrical switches. In another example, the smart electrical switches 102 may perform the necessary actions on the devices 104, on receiving necessary commands/signals being provided by other smart electrical switches. In another example, the smart electrical switches 102 may perform the necessary actions on the device 104, on receiving an assistance/approval from the user(s). In another example, the smart electrical switches 102 can receive/send the control notification(s) from/to other switches and/or compatible devices that may be dependent or have dependence on the target eco-system to perform the respective necessary actions on the devices 104. In another example, the smart electrical switches 102 can receive/send the control notification(s) from/to the required external service providers to perform the necessary actions on the devices 104. In another example, the smart electrical switches 102 receive/send the control notification(s) from/to the required external service providers to grant access to remotely control certain pre-specified functions of the devices 104 (or category of devices) via an application programming interface(s) (API). In another example, the smart electrical switches 102 can receive/send the control notification(s) from/to the required external service providers for approval (via human machine interface on the controller module, and/or application on the web/mobile) of the necessary action(s).

In an embodiment, the switch controller 106 may be configured to generate an anomaly notification for predictive maintenance and controlling of the smart electrical switches 102 and the associated devices 104, on receiving the condition monitoring data from the smart electrical switches 102.

For predictive maintenance and controlling of the smart electrical switches 102, the switch controller 106 can provide the condition monitoring data of the devices 104 received from each smart electrical switch 102 to a neural network module 302a. Examples of the neural network module 302a may be, but is not limited to, a machine learning network, a convolutional neural network (CNN), a deep neural network (DNN), a recurrent neural network (RNN), a restricted Boltzmann Machine (RBM), a deep belief network (DBN), a bidirectional recurrent deep neural network (BRDNN), generative adversarial networks (GAN), a deep Q-networks, an Artificial Intelligence (AI) model, a regression based neural network, and so on. The neural network module 302a can include a plurality of nodes, which may be arranged in layers. Examples of the layers may be, but is not limited to, a convolutional layer, an activation layer, an average pool layer, a max pool layer, a concatenated layer, a dropout layer, a fully connected layer, a SoftMax layer, and so on. A topology of the layers of the neural network module 302a may vary based on the type of the correlation module. In an example, the neural network module 302a may include an input layer, an output layer, and a hidden layer. The input layer can receive an input (for example: training data depicting anomalies identified with respect to the condition monitoring data of each device 104 associated with each smart electrical switch 102) and forward the received input to the hidden layer. The hidden layer can transform the input received from the input layer into a representation, which can be used for generating the output in the output layer. The hidden layers can extract useful/low level features from the input, introduce non-linearity in the network and reduce a feature dimension to make the features equivariant to scale and translation. The nodes of the layers may be fully connected via edges to the nodes in adjacent layers. The input received at the nodes of the input layer may be propagated to the nodes of the output layer via an activation function that calculates the states of the nodes of each successive layer in the network based on coefficients/weights respectively associated with each of the edges connecting the layers.

The neural network module 302a can analyze the condition monitoring data of the devices 104 connected with each smart electrical switch 102 and generate a linear or non-linear algebraic equation to establish a relation between the parameters of the devices 104 and the associated target eco-system (which have been indicated by the condition monitoring data). The neural network module 302a can then perform a regression analysis on the established relation between the parameters of the devices 104 and the associated target eco-system and identify the parameters of the devices 104 that have anomalies. The neural network module 302a can also determine future breakdown of the at least one device 104 or its requirement for maintenance services. The neural network module 302a can determine user/usage behavior of the devices 104 based on learning from the past/previous usage patterns of the devices 104.

On identifying the parameters of the at least one device 104 that have anomalies, by the neural network module 302a, the switch controller 106 can identify the smart electrical switches 102 related to the corresponding at least one device 104 (associated with the parameters that have the anomalies) for additional analysis. The switch controller 106 can analyze details of the identified smart electrical switches 102 to detect the anomalies associated with the smart electrical switches 102, identify a frequency of such anomalies, and to determine whether there is a distinct pattern in such anomalies with respect to at least one of, the timestamp, the room ID, the home ID, and so on.

On detecting the anomalies associated with the smart electrical switches 102 and/or the devices 104, the switch controller 106 can generate the anomaly notification for maintenance and controlling of the smart electrical switches 102 and/or the devices 104 associated with the anomalies. The switch controller 106 can send the anomaly notification to the user and/or the external service provider for the maintenance and controlling of the smart electrical switches 102 and/or the devices 104. The anomaly notification may include information such as, but not limited to, the anomalies associated with the smart electrical switches 102 and/or the devices 104 connected with smart electrical switches 102, the frequency of such anomalies, the distinct pattern in such anomalies, and so on.

In an embodiment, the switch controller 106 may be configured to identify certain kinds of loads that need to be switched OFF in order to meet the load regulation criteria. The load regulation criteria may be stored in the database 110. The load regulation criteria may be set by the user through a user device and/or a smart energy component installed in the same ecosystem. Examples of a smart energy component include, but are not limited to, a smart energy management system, a smart electrical panel, and a smart energy meter The load regulation criteria may also be set by the external service provider. The load regulation criteria may be stored on a cloud database 110 through an application on the web/mobile and/or a smart energy component that is installed in the ecosystem. The smart switches 102 can identify themselves and communicate the type of load/device 104 connected to it with the smart energy component. The smart energy component can send ON/OFF commands based on the load regulation criteria. An external service provider may be able to send the ON/OFF commands to the switch controller 106. In the case where the smart energy component is installed in the ecosystem, the smart energy component may send the ON/OFF commands simultaneously to the switch controller 106 and smart switch 102. In an example, the load regulation criteria may be set as a one-time programmable setting by the external service providers. In another example, the load regulation criteria may have multiple layers with different priority levels and each layer being set by the different external service providers. In such a case, the relevant load regulation criteria may be selected based on the priority level at that time. Settings in the layers of the load regulation criteria with higher priority levels can override the prevalent settings as need and/or situation arises.

FIG. 1 shows exemplary blocks of the control system 100, but it is to be understood that other embodiments are not limited thereon. In other embodiments, the control system 100 may include less or more number of blocks. Further, the labels or names of the blocks are used only for illustrative purpose and does not limit the scope of the embodiments herein. One or more blocks can be combined together to perform same or substantially similar function in the control system 100.

In other embodiments incorporating a sub switch 112, the sub switch 112 may comprise a power base 212 and a user controller 214. The power base 212 and user controller 214 of the sub switch 112 may comprise of the same components within the power base 202 and user controller 204 of the smart switch 102, respectively. The communication interface of the sub switch 112 may enable the sub switch 112 to connect with the smart switch 102 and/or switch controller 106 through a wireless personal area network (WPAN) through a networking protocol such as Bluetooth, Bluetooth Low Energy, Zigbee, NFC, or Thread (2.4 GHz) in either star or mesh topology. The sub switch 112 may comprise of sensors that are relevant to the device 104 associated with the sub switch 112. For example, a sub switch 112 associated with a device 104, such as a refrigerator, may comprise a temperature sensor and light sensor. The sub switch 112 may comprise a memory, a microcontroller, a radio frequency transceiver, and a digital audio processor. A user may communicate with the sub switch 112 directly, or indirectly through the smart switch 102, with the help of the user computing device.

In other embodiments, the sub switch 112 may have fewer components than the smart switch 102, resulting in the sub switch 112 having a limited availability of features and functionality compared to the smart switch 102. An example of a limited functionality of the sub switch 112 may be where the sub switch 112 is unable to directly communicate with the switch controller 106, but instead can indirectly communicate with the switch controller 106 by using the the smart switch 102 as an intermediary. An advantage with having the sub switch 112 only indirectly communicate with the switch controller 106 can be the reduction of nodes connecting to the switch controller 106, thereby reducing the risk of a security breach. An example of a limited feature of the sub switch 112 compared with the smart switch 102 can be the lack of an advanced user interface, such as a touch screen display or voice input interface. An advantage of the sub switch 112 not having an advanced user interface may be that in an embodiment of the system 100 having a smart switch 102 and a sub switch 112, there may be a lack of redundancy, as only the smart switch 102 may have the advanced user interface rather than the sub switch 112 having one as well. This can also help in reducing the costs associated with implementing the system 100 as a sub switch 112 having limited features and functionality compared to the smart switch 102, can reduce the cost of the sub switch 112.

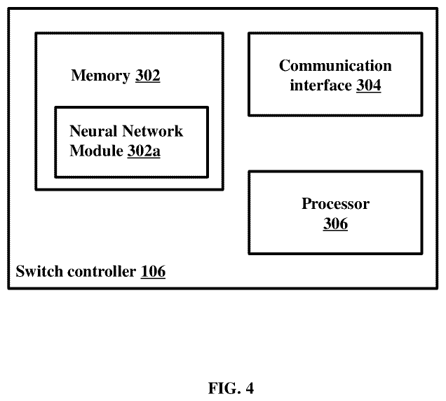

FIG. 4 is an example block diagram depicting components of the switch controller 106, according to embodiments as disclosed herein. The switch controller 106 can include a memory 302, a communication interface 304, and a processor 306.

The memory 302 may store at least one of, the identifiers assigned to each of the smart electrical switches 102 and/or the devices 104, the usage patterns of the devices 104, the anomalies detected with the smart electrical switches 102 and/or the devices 104, and so on. The memory 302 may also store the neural network module 302a, that may be processed by the processor 306 to detect the anomalies associated with the smart electrical switches and/or the devices 104.

The communication interface 304 may be configured to enable the switch controller 106 to communicate with at least one of, the smart electrical switches 102, the user devices, and so on using the communication methods supported by the communication network. All communication facilitated by the communication interface 304 may be encrypted or decrypted by a security element.

The processor 306 may include one or a plurality of processors. The one or a plurality of processors may be a general purpose processor, such as a central processing unit (CPU), an application processor (AP), or the like, a graphics-only processing unit such as a graphics processing unit (GPU), a visual processing unit (VPU), and/or an Artificial Intelligence (AI)-dedicated processor such as a neural processing unit (NPU).

The processor 306 may be configured to:
receive the condition monitoring data of the devices 104 from the smart electrical switches 102;
analyze the received condition monitoring data of the devices 104 to determine the usage context of the devices 104 and generate the control notification to the smart electrical switches 102 for performing the necessary actions on the devices 104, based on the determined usage context of the devices 104;
process the neural network module 302a to detect the smart electrical switches 102 and/or the devices 104 associated with the anomalies, the frequency of such anomalies, and the distinct pattern in such anomalies based on the received condition monitoring data of the devices 104;
analyze the received condition monitoring data of the devices 104 to identity the certain kinds of loads that need to be switched OFF in order to meet the load regulation criteria.

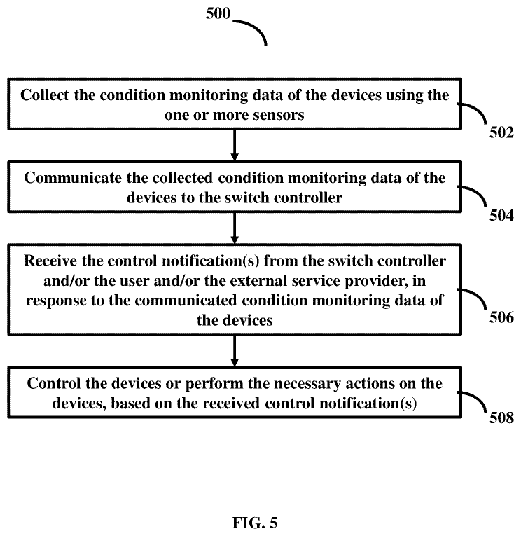

FIG. 5 is a flow diagram depicting functionalities of the smart electrical switch(es) 102, according to embodiments as disclosed herein.

At step 502, the smart electrical switch 102 collects the condition monitoring data of the devices 104 using the one or more sensors. The condition monitoring data may indicate the conditions/parameters of the devices 104 and their target eco-system. The one or more sensors may be implemented in the power base 202 and the user controller 204 of the smart electrical switch. At step 504, the smart electrical switch 102 communicates the collected condition monitoring data of the devices 104 to the switch controller 106.

At step 506, the smart electrical switch 102 receives the control notification(s) from the switch controller 106 and/or the user and/or the external service provider, in response to the communicated condition monitoring data of the devices 104. At step 508, the smart electrical switch 102 controls the devices 104 or performs the necessary actions on the devices 104, based on the received control notification(s). The various actions may be performed in the order presented, in a different order or simultaneously. Further, in some embodiments, some actions listed in FIG. 5 may be omitted.

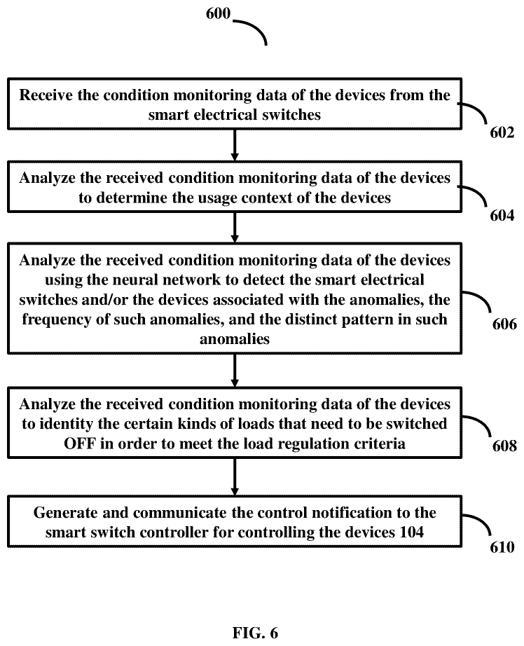

FIG. 6 is a flow diagram depicting a method 600 for maintenance and controlling of the smart electrical switches 102 and the associated devices 104, according to embodiments as disclosed herein.

At step 602, the method includes receiving, by the switch controller 106, the condition monitoring data of the devices 104 from the smart electrical switches 102.

At step 604, the method includes analyzing, by the switch controller 106, the received condition monitoring data of the devices 104 to determine the usage context of the devices 104.

At step 606, the method includes analyzing, by the switch controller 106, the received condition monitoring data of the devices 104 using the neural network to detect the smart electrical switches 102 and/or the devices 104 associated with the anomalies, the frequency of such anomalies, and the distinct pattern in such anomalies. The switch controller 106 sends the anomaly notification to the user and/or the external service provider to inform about the anomalies detected with the smart electrical switches 102 and/or the associated devices 104.

At step 608, the method includes analyzing, by the switch controller 106, the received condition monitoring data of the devices 104 to identity the certain kinds of loads that need to be switched OFF in order to meet the load regulation criteria.

At step 610, the method includes generating and communicating, by the switch controller 106, the control notification to the smart switch controller 106 for controlling the devices 104. The control notification may be generated based on at least one of, the determined usage context of the devices 104, the anomalies detected with the devices 104, and the identified certain kinds of loads that need to be switched OFF. The various actions in the method 600 may be performed in the order presented, in a different order or simultaneously. Further, in some embodiments, some actions listed in FIG. 6 may be omitted.

The embodiments disclosed herein can be implemented through at least one software program running on at least one hardware device and performing network management functions to control the elements. The elements shown in FIGS. 1, 2, 3, and 4 can be at least one of a hardware device, or a combination of hardware device and software module.

The embodiments disclosed herein describe methods and systems for remotely controlling smart electrical switches and associated devices. Therefore, it is understood that the scope of the protection is extended to such a program and in addition to a computer readable means having a message therein, such computer readable storage means contain program code means for implementation of one or more steps of the method, when the program runs on a server or mobile device or any suitable programmable device. The method is implemented in a preferred embodiment through or together with a software program written in e.g. Very high speed integrated circuit Hardware Description Language (VHDL) another programming language or implemented by one or more VHDL or several software modules being executed on at least one hardware device. The hardware device can be any kind of portable device that can be programmed. The device may also include means which could be e.g. hardware means like e.g. an ASIC, or a combination of hardware and software means, e.g. an ASIC and an FPGA, or at least one microprocessor and at least one memory with software modules located therein. The method embodiments described herein could be implemented partly in hardware and partly in software. Alternatively, the invention may be implemented on different hardware devices, e.g. using a plurality of CPUs.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of embodiments, those skilled in the art will recognize that the embodiments herein can be practiced with modification within the scope of the embodiments as described herein.

1. A system, comprising:
a smart switch, wherein the smart switch is configured to operate or control a device, wherein the smart switch comprises:
a power base, wherein the power base comprises a direct current power supply, at least one voltage regulator, a relay, a power measurement element, a microcontroller, and a radio frequency transceiver; and
a user controller, wherein the user controller comprises a direct current power supply, a direct current to direct current voltage regulator, a microcontroller, a radio frequency transceiver, a digital audio processor, a microphone; and
a switch controller, wherein the switch controller comprises a memory to store at least one identifier of the smart switch, a communication interface for enabling communication between the switch controller and the smart switch, and a processor, wherein the switch controller 106 receives data regarding the device from the smart switch, and
wherein at least one sensor is present in either the power base or the user controller.

2. The system of claim 1, further comprising a sub switch, wherein the sub switch comprises a power base and a user controller, wherein the sub switch is connected to the device, and wherein the smart switch is configured to operate or control the device via the sub switch.

3. The system of claim 2, wherein the sub switch is configured to transmit data about the device to the switch controller via the smart switch.

4. The system of claim 1, wherein the power base is connected to the user controller through a plug connector.

5. The system of claim 1, further comprising a security element, wherein the security element encrypts and decrypts all communication from and to at least one of the following devices: smart switch and switch controller.

6. The system of claim 1, wherein the switch controller 106 further comprises a neural network module that provides predictive maintenance and control of the smart switch based on the data about the device.

7. The system of claim 6, wherein the switch controller generates an anomaly notification based on an output from the neural network module.

8. The system of claim 1, wherein the switch controller is configured to receive a load regulation criteria and determine if at least one device among a plurality of devices needs to be turned off.

9. The system of claim 1, wherein the smart switch is configured to collect data regarding the device through at least one sensor in the power base or user controller, wherein
the at least one sensor senses at least one of the following: proximity of a user from the smart switch, proximity of a user from the device, ambient light conditions, infrared motion detection, temperature, air quality, gas detection, and smoke; and
the smart switch is configured to perform an action on the device based on a control notification generated from the switch controller, wherein the control notification is dependent on the data regarding the device transmitted by the smart switch.

10. The system of claim 1, wherein the smart switch further comprises of a user interface, wherein the user interface includes at least one of the following: a display with a touch screen, at least one push button, and at least one slider switch.

11. The system of claim 1, wherein the smart switch is remotely controlled by at least one of the following: a mobile application and a voice input.

12. A method for maintaining and controlling at least one smart switch and at least one device, comprising:
receiving, by a switch controller, data regarding the at least one device from the at least one smart switch;
analyzing, by a neural network module of the switch controller, the received data regarding the at least one device for an anomaly associated with at least one of: the at least one smart switch and the at least one device
determining, by a processor of the switch controller, whether the at least one device meets a load regulation criteria; and
generating and transmitting at least one control notification based on an output of at least one of the following: the neural network module and the processor.

13. The method of claim 12, wherein the control notification generated and transmitted based on an output of the processor results in the smart switch either letting the at least one device to continue operating or switching off the at least one device.

14. The method of claim 12, wherein the control notification is transmitted to at least one of the following: a user and an external service provider.
